(19) United States
(12) Patent Application Publication
(10) Pub. No.: US 2025/0251434 A1
(43) Pub. Date: Aug. 7, 2025

(54) APPARATUS, SYSTEM, AND METHOD FOR EFFICIENTLY TESTING DEVICE RADIATION FOR SPURIOUS EMISSIONS

(71) Applicant: Meta Platforms Technologies, LLC, Menlo Park, CA (US)

(72) Inventors: Yuqi Liu, San Jose, CA (US); Jianqi Xue, San Jose, CA (US); Jie Zhang, Newark, CA (US); Alkan Ozturk, San Diego, CA (US)

(21) Appl. No.: 18/435,798

(22) Filed: Feb. 7, 2024

(51) Int. Cl. G01R 29/08; G01R 29/10

(52) U.S. Cl. CPC G01R 29/0878; G01R 29/105

(57) ABSTRACT

An apparatus that facilitates and/or supports efficiently testing device radiation for spurious emissions may include a chamber that includes a plurality of interior sides. This apparatus may also include a plurality of antennas coupled to the plurality of interior sides, and the plurality of antennas may be configured to receive radiation emitted by a device under test. This apparatus may further include a controller communicatively coupled to the plurality of antennas, and the controller may be configured to obtain measurements of spurious emissions in the radiation. Various other apparatuses, systems, and methods are also disclosed.

### BRIEF DESCRIPTION OF DRAWINGS

The accompanying drawings illustrate a number of example embodiments and are a part of the specification. Together with the following description, these drawings demonstrate and explain various principles of the instant disclosure.

FIG. 1 is an illustration of an exemplary apparatus for efficiently testing device radiation for spurious emissions according to one or more implementations of this disclosure.

FIG. 2 is an illustration of an exemplary chamber for efficiently testing device radiation for spurious emissions according to one or more implementations of this disclosure.

FIG. 3 is an illustration of an exemplary chamber for efficiently testing device radiation for spurious emissions according to one or more implementations of this disclosure.

FIG. 4 is an illustration of an exemplary system for efficiently testing device radiation for spurious emissions according to one or more implementations of this disclosure.

FIG. 5 is an illustration of an exemplary chamber for efficiently testing device radiation for spurious emissions according to one or more implementations of this disclosure.

FIG. 6 is a flow diagram of an exemplary method for efficiently testing device radiation for spurious emissions according to one or more implementations of this disclosure.

While the exemplary embodiments described herein are susceptible to various modifications and alternative forms, specific embodiments have been shown by way of example in the appendices and will be described in detail herein. However, the exemplary embodiments described herein are not intended to be limited to the particular forms disclosed. Rather, the instant disclosure covers all modifications, combinations, equivalents, and alternatives falling within this disclosure.

### DETAILED DESCRIPTION OF EXEMPLARY EMBODIMENTS

The present disclosure is generally directed to apparatuses, systems, and methods for efficiently testing device radiation for spurious emissions. As will be explained in greater detail below, these apparatuses, systems, and methods may provide numerous features and benefits.

In some examples, regulatory authorities and/or government agencies, such as the Federal Communications Commissions (FCC), may regulate the amount of radiation emitted by consumer electronics. For example, a regulatory authority may require that all consumer electronics emit less than a given amount of total radiated power (TRP), effective radiated power (ERP), and/or equivalent isotopically radiated power (EIRP). In this example, to ensure compliance with the given amount of TRP, ERP, and/or EIRP, manufacturers and/or vendors may perform radiation testing on their consumer electronics.

As part of such testing, the manufacturers and/or vendors may detect and/or measure the amount of spurious emissions radiated by the consumer electronics. To do so, the manufacturers and/or vendors may install examples and/or prototypes of the consumer electronics inside a chamber. Once installed inside the chamber, the examples and/or prototypes of the consumer electronics may be subjected to radiation testing at different angles and/or over long periods of time to determine whether the examples and/or prototypes comply with the given amount of TRP, ERP, and/or EIRP.

Some chambers that facilitate and/or support such radiation testing may consume and/or occupy a significant amount of space and/or cost a significant amount of money. For example, a common radiation-testing chamber may measure 9 meters in length, 6 meters in width, and/or 6 meters in height with the effective 3-meter measurement distance. Additionally or alternatively, this common 5M radiation-testing chamber may cost upwards of 1 million US dollars to construct. Moreover, some 5M chambers that facilitate and/or support such radiation testing may include and/or implement a single antenna for measuring spurious emissions. Unfortunately, the single-antenna architecture of such 5M chambers may require upwards of 1,000 hours to complete the necessary TRP, ERP, and/or EIRP testing for determining compliance.

Alternatives to such 5M chambers may include and/or represent a smaller, faster, and/or more cost-effective solution. For example, a compact radiation-testing chamber may measure approximately 1.8 meters in length, 1.7 meters in width, and/or 2.1 meters in height. Additionally or alternatively, this compact radiation-testing chamber may cost approximately 100,000 US dollars to construct. Moreover, this compact radiation-testing chamber may include and/or implement multiple antennas (e.g., 2, 3, 4, or more antennas) for measuring spurious emissions. The multi-antenna architecture of this compact chamber may facilitate and/or support approximately 200 hours to complete the necessary TRP, ERP, and/or EIRP testing for determining compliance.

In some examples, a compact radiation-testing chamber may provide various other advantages, benefits, and/or improvements over certain 5M chambers. For example, a compact radiation-testing chamber may include and/or implement a mobility feature that facilitates and/or supports movement throughout a facility and/or from one location to another. Additionally or alternatively, the compact radiation-testing chamber may include and/or implement an externally mounted user interface (e.g., a touchscreen controller) that facilitates and/or supports a self-contained testing environment. In one example, the compact radiation-testing chamber may include and/or implement radiation-absorbent material and/or beams that line or cover the interior floor, ceiling, and/or walls to mitigate and/or absorb radiation reflections.

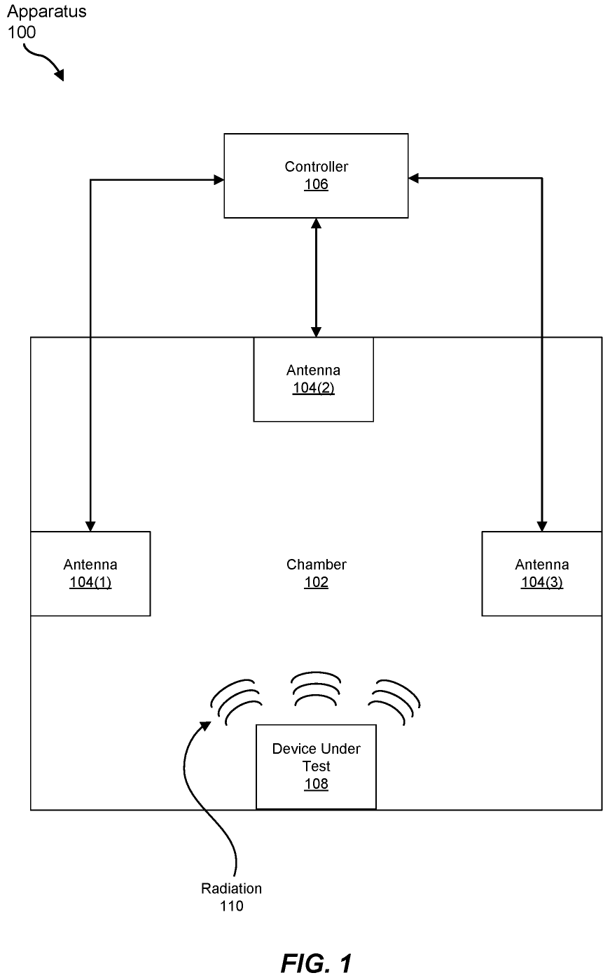

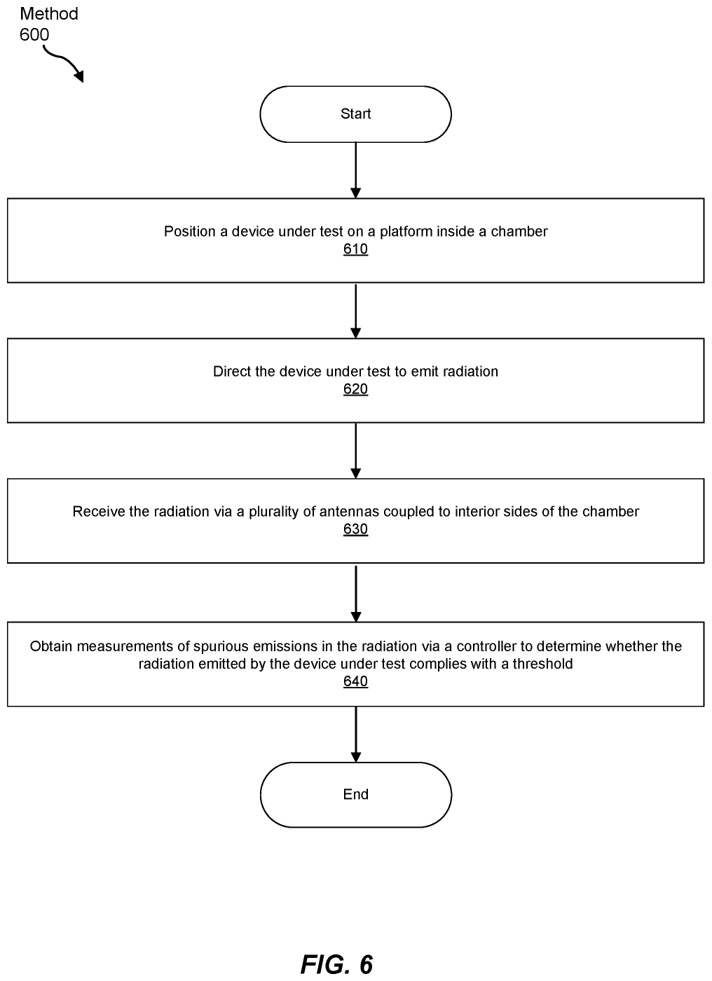

The following will provide, with reference to FIGS. 1-5, detailed descriptions of exemplary apparatuses, devices, systems, components, and corresponding configurations or implementations for efficiently testing device radiation for spurious emissions. In addition, detailed descriptions of methods for efficiently testing device radiation for spurious emissions will be provided in connection with FIG. 6.

FIG. 1 illustrates an exemplary apparatus 100 for efficiently testing device radiation for spurious emissions. As illustrated in FIG. 1, apparatus 100 may include and/or represent a chamber 102, antennas 104(1)-(3), and/or a controller 106. In some examples, chamber 102 may include and/or represent a plurality of sides (e.g., walls, ceiling, and/or floor) with both interior and exterior surfaces. In one example, antennas 104(1)-(3) may be coupled, secured, and/or attached to a plurality of interior sides and/or surfaces. In this example, antennas 104(1)-(3) may each be configured and/or arranged to receive and/or measure radiation 110 emitted by a device under test (DUT) 108.

In some examples, controller 106 may be communicatively coupled to antennas 104(1)-(3). In one example, controller 106 may be configured and/or programmed to take and/or obtain measurements of spurious emissions in radiation 110. In certain implementations, apparatus 100 may facilitate and/or support performing, conducting, and/or completing TRP, ERP, and/or EIRP testing for determining whether DUT 108 complies with certain regulatory requirements and/or parameters (e.g., spurious emission levels).

In some examples, chamber 102 may include and/or represent any type or form of structure, room, cavity, compartment, assembly, and/or enclosure that facilitates and/or supports measuring and/or testing radiation 110 emitted by devices. In one example, chamber 102 may be sized, dimensioned, and/or shaped in any suitable way to facilitate and/or support radiation testing for compliance purposes. For example, chamber 102 may measure approximately 1.8 meters in length, 1.7 meters in width, and/or 2.1 meters in height. In one example, chamber 102 may include and/or contain a variety of different materials. Examples of such materials include, without limitation, plastics, acrylics, polyvinyls, polyesters, metals, nylons, conductive materials, rubbers, neoprene, carbon fibers, composites, low-permittivity materials, low-reflection materials, combinations or variations of one or more of the same, and/or any other suitable materials.

In some examples, antennas 104(1)-(3) may each include and/or represent any type or form of conductive component, device, and/or structure capable of radiating and/or resonating radio frequencies. In one example, antennas 104(1)-(3) may each include and/or represent a metallic structure mounted to one of the interior sides of chamber 102. In this example, antennas 104(1)-(3) may be sized, dimensioned, and/or shaped in any suitable way to facilitate and/or support radiation testing for compliance purposes. For example, antennas 104(1)-(3) may be configured and/or designed to receive and/or measure spurious emissions in radiation ranging from 1 gigahertz to 21 gigahertz. In one example, antennas 104(1)-(3) may include and/or contain any of various conductive materials. Examples of such conductive materials include, without limitation, coppers, golds, steels, alloys, silvers, nickels, aluminums, variations or combinations of one or more of the same, and/or any other suitable type of conductive materials.

In some examples, controller 106 may include and/or represent electrical and/or electronic circuitry capable of processing, applying, modifying, transforming, displaying, transmitting, receiving, and/or executing data for apparatus 100. In one example, controller 106 may detect, take, and/or obtain measurements of spurious emissions in radiation 110. Additionally or alternatively, controller 106 may launch, perform, and/or execute certain executable files, code snippets, and/or computer-readable instructions to facilitate and/or support efficiently testing device radiation for spurious emissions. Although illustrated as a single unit in FIG. 1, controller 106 may include and/or represent a collection of multiple circuits, processing units, and/or electrical components that work and/or operate in conjunction with one another. Examples of controller 106 include, without limitation, processing devices, microprocessors, microcontrollers, central processing units (CPUs), graphics processing units (GPUs), application-specific integrated circuits (ASICs), field-programmable gate arrays (FPGAs), systems on chips (SoCs), switching devices, parallel accelerated processors, tensor cores, integrated circuits, chiplets, optical modules, receivers, transmitters, transceivers, portions of one or more of the same, variations or combinations of one or more of the same, and/or any other suitable controllers.

In some examples, DUT 108 may include and/or represent any type or form of device, component, and/or mechanism that undergoes radiation testing for compliance purposes. For example, DUT 108 may include and/or represent a head-mounted display (HMD). In one example, the term “head-mounted display” and/or the abbreviation “HMD” may refer to any type or form of display device or system that is worn on or about a user's face and displays virtual content—such as computer-generated objects, virtual-reality (VR) content, and/or augmented-reality (AR) content—to the user. Additional examples of DUT 108 include, without limitation, personal computers, client devices, laptops, tablets, desktops, servers, cellular phones, Personal Digital Assistants (PDAs), multimedia players, embedded systems, wearable devices, gaming consoles, routers, switches, hubs, modems, bridges, repeaters, gateways, multiplexers, network adapters, network interfaces, portions of one or more of the same, variations or combinations of one or more of the same, and/or any other suitable devices. In certain implementations, DUT 108 may radiate radio-frequency (RF) signals and/or spurious emissions ranging from 1 gigahertz to 21 gigahertz.

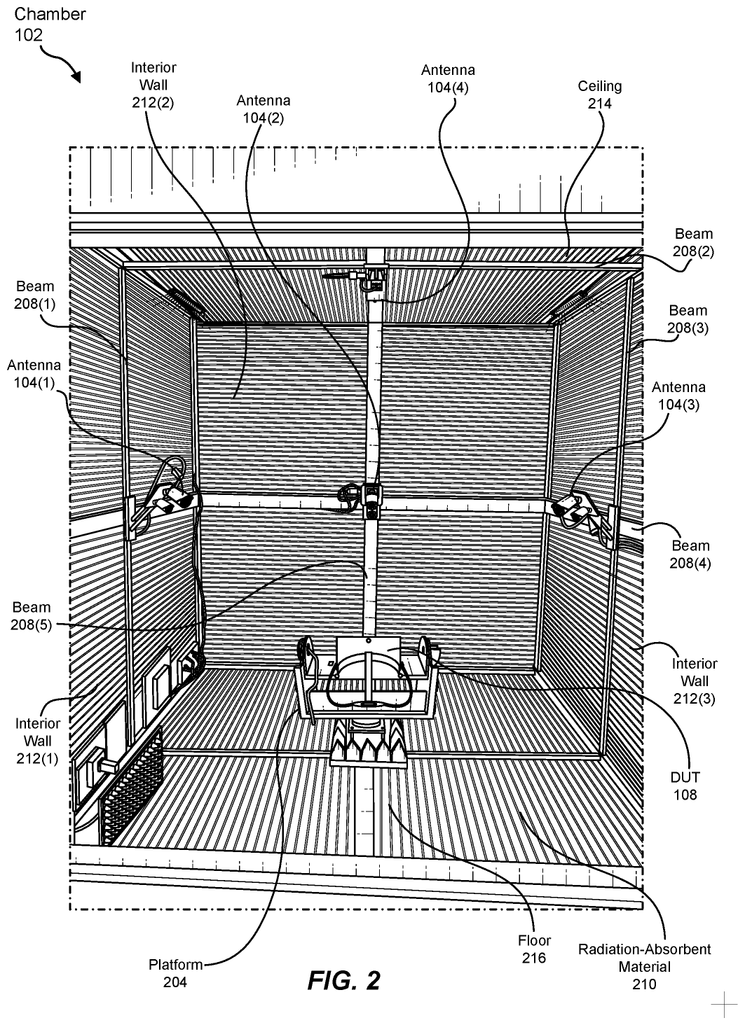

FIG. 2 illustrates an interior view of exemplary chamber 102 for efficiently testing device radiation for spurious emissions. In some examples, chamber 102 may include and/or represent certain devices, components, and/or features that perform and/or provide functionalities that are similar and/or identical to those described above in connection with FIG. 1. As illustrated in FIG. 2, chamber 102 may include and/or represent interior walls 212(1)-(3), a ceiling 214, and/or a floor 216.

In some examples, chamber 102 may include and/or implement a platform 204 movably coupled, secured, and/or mounted to floor 216. In such examples, platform 204 may position, hold, and/or support DUT 108 for radiation testing. In this example, platform 204 may be movable and/or configured to secure DUT 108 in place relative to antennas 104(1)-(4). Additionally or alternatively, platform 204 may rotate and/or move DUT 108 in one direction or another to enable antennas 104(1)-(4) to receive radiation 110 from DUT 108 at different angles and/or to take the measurements of spurious emissions from different angles. In certain implementations, platform 204 may be moved in a horizontal direction and/or a vertical direction.

In some examples, interior walls 212(1) and 212(2) may be substantially orthogonal, perpendicular, and/or right-angled relative to one another. Similarly, interior walls 212(2) and 212(3) may be substantially orthogonal, perpendicular, and/or right-angled relative to one another. Accordingly, interior walls 212(1) and 212(3) may be substantially parallel and/or coplanar relative to one another. In one example, ceiling 214 and floor 216 may be substantially orthogonal, perpendicular, and/or right-angled relative to interior walls 212(1)-(3). In this example, ceiling 214 and floor 216 may be substantially parallel and/or coplanar relative to one another.

In some examples, antenna 104(1) may be mounted, coupled, and/or secured to interior wall 212(1). In one example, antenna 104(2) may be mounted, coupled, and/or secured to interior wall 212(2). Similarly, antenna 104(3) may be mounted, coupled, and/or secured to interior wall 212(3). Additionally or alternatively, antenna 104(4) may be mounted, coupled, and/or secured to ceiling 214.

In some examples, antennas 104(1)-(3) may be positioned and/or arranged coplanarly relative to one another. In other words, antennas 104(1)-(3) may be positioned and/or arranged equidistant from DUT 108 along the same plane. For example, antennas 104(1)-(3) may be positioned and/or arranged along a horizontally central plane and/or a horizontal midplane of chamber 102. Additionally or alternatively, platform 204, DUT 108, and/or antennas 104(1), 104(3), and 104(4) may be positioned and/or arranged along a vertically central plane and/or a vertical midplane of chamber 102. Accordingly, antenna 104(4) may be positioned and/or arranged above and/or over platform 204 and/or DUT 108 inside chamber 102.

In some examples, some or all of the interior sides of chamber 102 may be lined and/or covered with or by radiation-absorbent material 210. For example, interior walls 212(1)-(3) may be lined and/or covered with or by radiation-absorbent material 210. Additionally or alternatively, ceiling 214 and/or floor 216 may be lined and/or covered with or by radiation-absorbent material 210. In certain implementations, radiation-absorbent material 210 may mitigate reflections of RF signals and/or radiation 110 within chamber 102.

In some examples, some or all of the interior sides of chamber 102 may include and/or represent segments and/or portions that are lined and/or covered with or by beams composed of radiation-absorbent material. For example, beams 208(1)-(5) may be applied, coupled, mounted, and/or attached to one or more of interior walls 212(1)-(3), ceiling 214, and/or floor 216. More specifically, beam 208(1) may be secured vertically along interior wall 212(1), beam 208(2) may be secured horizontally along ceiling 214, beam 208(3) may be secured vertically along interior wall 212(3), beam 208(4) may be secured horizontally along interior wall 212(3), and/or beam 208(5) may be secured vertically along interior wall 212(2). In one example, beams 208(1)-(5) may be composed of low-permittivity material (e.g., polyvinyl).

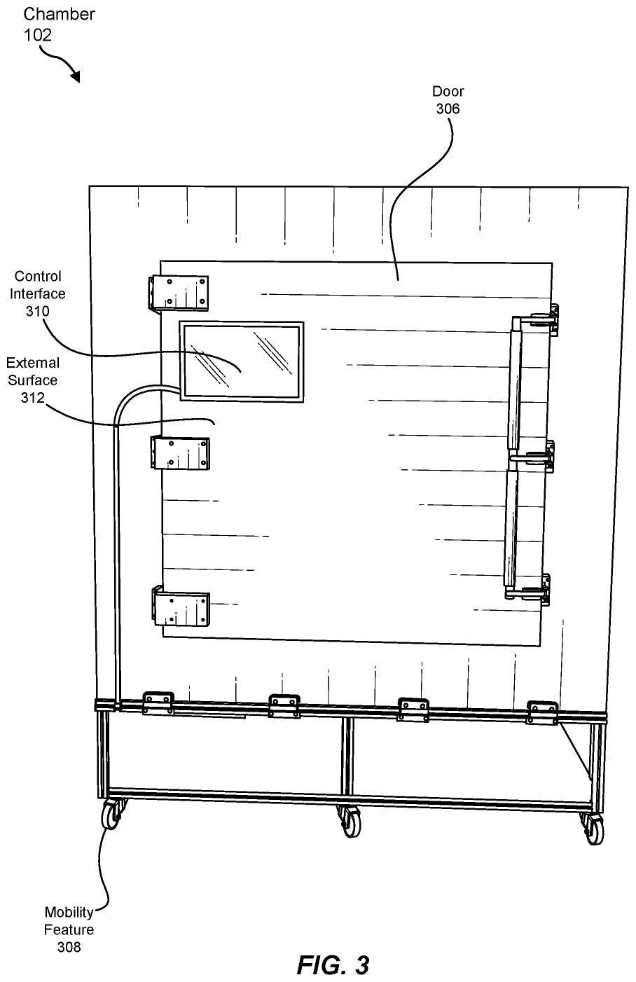

FIG. 3 illustrates an exterior view of exemplary chamber 102 for efficiently testing device radiation for spurious emissions. In some examples, chamber 102 may include and/or represent certain devices, components, and/or features that perform and/or provide functionalities that are similar and/or identical to those described above in connection with either FIG. 1 or FIG. 2. As illustrated in FIG. 3, chamber 102 may include and/or represent a door 306 movably mounted, coupled, and/or secured to one of the exterior sides and/or walls. In one example, chamber 102 may include and/or represent a full and/or complete enclosure when door 306 is closed. In this example, chamber 102 may include and/or represent a self-contained testing environment.

In some examples, chamber 102 may include and/or represent a control interface 310 mounted, coupled, and/or secured to door 306 and/or an external surface 312. In one example, control interface 310 may be communicatively coupled to controller 106 and/or antennas 104(1)-(4).

In some examples, control interface 310 may enable an administrator and/or analyst to initiate, perform, and/or control radiation testing of DUT 108. Additionally or alternatively, control interface 310 may enable an administrator and/or analyst to monitor, view, and/or observe the results of the radiation testing of DUT 108 and/or other happenings internal to chamber 102. Upon completion of the radiation testing, controller 106 may analyze and/or determine whether the radiation emitted by DUT 108 complies with a threshold of spurious emissions. In one example, if the amount of spurious emissions detected and/or measured in the radiation falls below the threshold, controller 106 may determine and/or conclude that the radiation emitted by DUT 108 complies with the amount of TRP, ERP, and/or EIRP required by a regulatory authority and/or government agency. In this example, if the amount of spurious emissions detected and/or measured in the radiation reaches the threshold or beyond, controller 106 may determine and/or conclude that the radiation emitted by DUT 108 fails to comply with the amount of TRP, ERP, and/or EIRP required by the regulatory authority and/or government agency.

In some examples, chamber 102 may include and/or represent a mobility feature 308 that facilitates and/or supports movement and/or relocation within a facility and/or from one location or another. In other words, mobility feature 308 may enable chamber 102 to move and/or be moved within a facility and/or from one location or another. In one example, mobility feature 308 may include and/or represent certain components that facilitate moving, driving, and/or steering chamber 102 in and/or around a laboratory. Examples of such components include, without limitation, carts, motors (such as direct current motors, alternating current motors, vibration motors, brushless motors, switched reluctance motors, synchronous motors, rotary motors, servo motors, coreless motors, stepper motors, and/or universal motors), axles, gears, drivetrains, wheels, treads, steering mechanisms, circuitry, electrical components, processing devices, memory devices, circuit boards, power sources, wiring, batteries, communication buses, combinations or variations of one or more of the same, and/or any other suitable components. In certain implementations, one or more of these components may move, turn, and/or rotate to drive or implement locomotion for chamber 102.

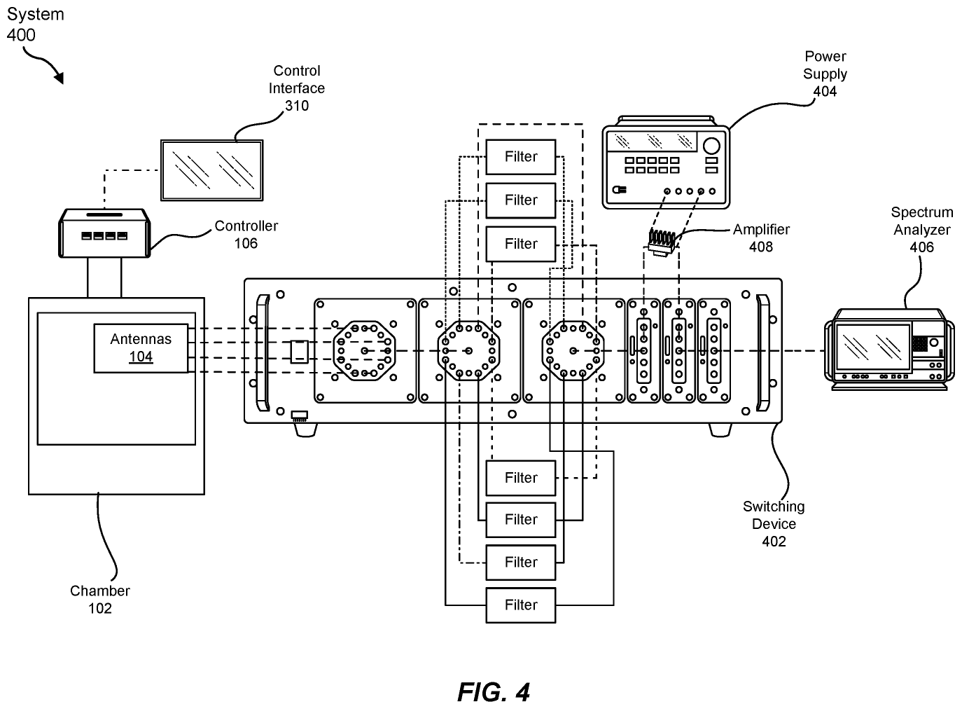

FIG. 4 illustrates an exemplary system 400 for efficiently testing device radiation for spurious emissions. In some examples, system 400 may include and/or represent certain devices, components, and/or features that perform and/or provide functionalities that are similar and/or identical to those described above in connection with any of FIGS. 1-3. As illustrated in FIG. 4, system 400 may include and/or represent chamber 102, antennas 104, controller 106, control interface 310, a switching device 402, a power supply 404, a spectrum analyzer 406, and/or an amplifier 408.

In some examples, switching device 402 may be configured to selectively activate at least one of antennas 104 at any given time. In such examples, switching device 402 may be configured to selectively deactivate at least one of antennas 104 at any given time. For example, switching device 402 may activate one of antennas 104 and deactivate all other antennas 104 at one moment. In this example, switching device 402 may activate another one of antennas 104 and deactivate all other antennas 104, including the previously active one, at a later moment. Accordingly, switching device 402 may cycle and/or sweep through antennas 104 for measuring radiation 110 at different angles. Although illustrated as separate and/or distinct devices in FIG. 4, controller 106 and switching device 402 may alternatively constitute and/or represent a single device or system in other embodiments.

In some examples, the active antenna may take one or more measurements of spurious emissions in radiation 110 emitted by DUT 108. In such examples, controller 106 may measure spurious emissions in radiation 110 as received by the active antenna. In one example, the inactive antenna may refrain from taking any measurements of spurious emissions in radiation 110 emitted by DUT 108.

In some examples, controller 106 may direct one or more of antennas 104 to perform an ambient scan of radiation 110 emitted by DUT 108. In one example, controller 106 may search the data resulting from the ambient scan for spurious emissions present in radiation 110. In this example, controller 106 may focus on, zoom in on, extract, and/or isolate the data representative of the spurious emissions. Additionally or alternatively, controller 106 may collect and/or aggregate the data representative of the spurious emissions for processing. Controller 106 may then determine, based at least in part on the processed data, whether or not DUT 108 complies with a standard of spurious emissions set and/or enforced by a regulatory authority and/or government agency. In other words, controller 106 may determine whether the spurious emissions detected and/or identified in radiation 110 complies with a threshold representative of the standard.

In some examples, controller 106 may direct each of antennas 104 to perform multiple passes during an ambient scan. For example, during an ambient scan, controller 106 may direct each of antennas 104 to perform a horizontally polarized pass and/or a vertically polarized pass. Accordingly, each of antennas 104 may detect, receive, and/or measure radiation 110 emitted by DUT 108 while horizontally polarized and also while vertically polarized.

In some examples, controller 106 may calibrate chamber 102 and/or antennas 104 to accurately measure radiation 110 emitted by DUT 108. For example, controller 106 may use a pre-calibrated reference antenna included in antennas 104 to compensate all the losses from the other antennas and/or corresponding cabling. In one example, controller 106 may subtract certain data points collected from known sources to determine and/or calculate path losses for all the chamber combinations and/or variables, including free space, cable loss, amplifiers, etc.

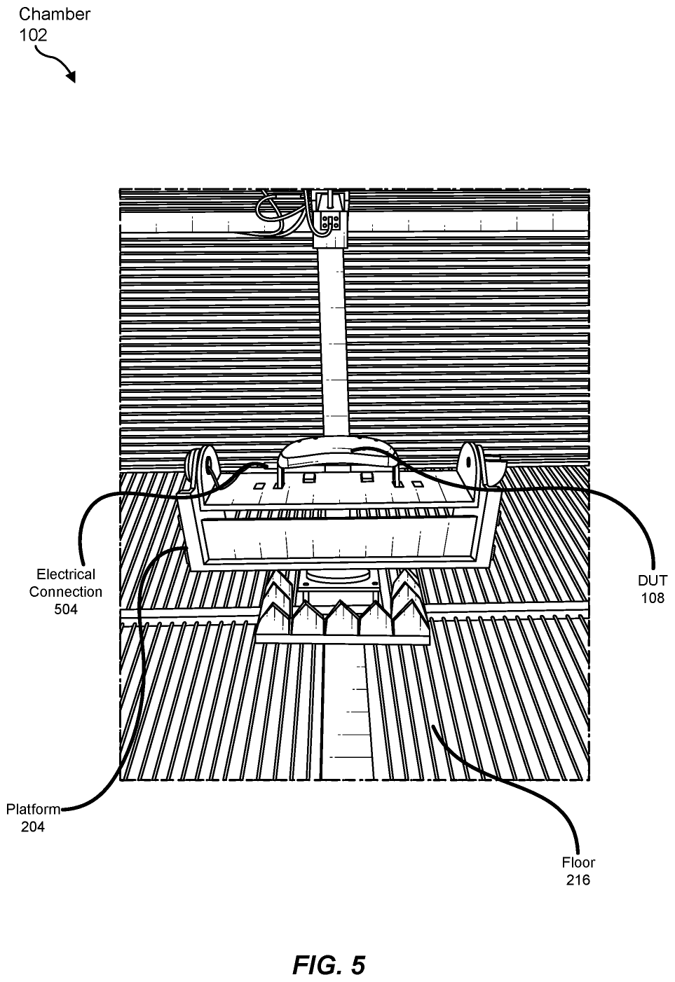

FIG. 5 illustrates an interior view of exemplary chamber 102 for efficiently testing device radiation for spurious emissions. In some examples, chamber 102 may include and/or represent certain devices, components, and/or features that perform and/or provide functionalities that are similar and/or identical to those described above in connection with any of FIGS. 1-4. As illustrated in FIG. 5, chamber 102 may include and/or represent DUT 108 installed for testing on platform 204. In one example, platform 204 may be fitted and/or equipped with an electrical connection 504.

In some examples, electrical connection 504 may provide a power source, a charging source, and/or a communication link for DUT 108 during radiation testing. In one example, DUT 108 may receive power and/or electric current via electrical connection 504 during radiation testing. Additionally or alternatively, DUT 108 may exchange data, commands, and/or instructions with one or more other devices (e.g., controller 106) via electrical connection 504 during testing.

In some examples, chamber 102 and/or platform 204 may be fitted and/or equipped to accept, receive, support, and/or use power at different voltage levels and/or standards (e.g., 110 volts and/or 230 volts). Additionally or alternatively, platform 204 may rotate and/or move DUT 108 to various positions within chamber 102 without disconnecting and/or disturbing electrical connection 504.

In some examples, the various apparatuses, devices, and systems described in connection with FIGS. 1-5 may include and/or represent one or more additional circuits, components, and/or features that are not necessarily illustrated and/or labeled in FIGS. 1-5. For example, the apparatuses, devices, and systems illustrated in FIGS. 1-5 may also include and/or represent additional analog and/or digital circuitry, onboard logic, transistors, RF transmitters, RF receivers, transceivers, antennas, resistors, capacitors, diodes, inductors, switches, registers, flipflops, digital logic, connections, traces, buses, semiconductor (e.g., silicon) devices and/or structures, processing devices, storage devices, circuit boards, sensors, packages, substrates, housings, combinations or variations of one or more of the same, and/or any other suitable components. In certain implementations, one or more of these additional circuits, components, and/or features may be inserted and/or applied between any of the existing circuits, components, and/or features illustrated in FIGS. 1-5 consistent with the aims and/or objectives described herein. Accordingly, the couplings and/or connections described with reference to FIGS. 1-5 may be direct connections with no intermediate components, devices, and/or nodes or indirect connections with one or more intermediate components, devices, and/or nodes.

In some examples, the phrase “to couple” and/or the term “coupling”, as used herein, may refer to a direct connection and/or an indirect connection. For example, a direct coupling between two components may constitute and/or represent a coupling in which those two components are directly connected to each other by a single node that provides continuity from one of those two components to the other. In other words, the direct coupling may exclude and/or omit any additional components between those two components.

Additionally or alternatively, an indirect coupling between two components may constitute and/or represent a coupling in which those two components are indirectly connected to each other by multiple nodes that fail to provide continuity from one of those two components to the other. In other words, the indirect coupling may include and/or incorporate at least one additional component between those two components.

In some examples, one or more components and/or features illustrated in FIGS. 1-5 may be excluded and/or omitted from the various apparatuses, devices, and/or systems described in connection with FIGS. 1-5. Although these apparatuses, devices, and/or systems are often described above in terms of their configurations and/or capabilities, these apparatuses, devices, and/or systems may also actually perform any of the functionalities, behaviors, and/or services associated with those configurations and/or capabilities. For example, a controller configured to obtain radiation measurements may actually obtain such radiation measurements.

FIG. 6 is a flow diagram of an exemplary method 600 for efficiently testing device radiation for spurious emissions. In one example, the steps shown in FIG. 6 may be achieved and/or accomplished by a computing equipment manufacturer or subcontractor that performs and/or conducts radiation testing. Additionally or alternatively, the steps shown in FIG. 6 may incorporate and/or involve certain sub-steps and/or variations consistent with the descriptions provided above in connection with FIGS. 1-5.

As illustrated in FIG. 6, method 600 may include the step of positioning a DUT on a platform inside a chamber (610). Step 610 may be performed in a variety of ways, including any of those described above in connection with FIGS. 1-5. For example, a computing equipment manufacturer or subcontractor may couple, fix, mount, secure, place, and/or position a DUT on a platform inside a chamber.

Method 600 may also include the step of directing the DUT to emit radiation (620). Step 620 may be performed in a variety of ways, including any of those described above in connection with FIGS. 1-5. For example, the computing equipment manufacturer or subcontractor may direct and/or cause the DUT to emit radiation for testing.

Method 600 may further include the step of receiving the radiation via a plurality of antennas coupled to interior sides of the chamber (630). Step 630 may be performed in a variety of ways, including any of those described above in connection with FIGS. 1-5. For example, a plurality of antennas coupled to interior sides of the chamber may detect, receive, and/or measure the radiation emitted by the DUT.

Method 600 may additionally include the step of obtaining measurements of spurious emissions in the radiation via a controller to determine whether the radiation emitted by the device under test complies with a threshold (640). Step 640 may be performed in a variety of ways, including any of those described above in connection with FIGS. 1-5. For example, a controller communicatively coupled to the antennas may perform, obtain, and/or distill measurements of spurious emissions in the radiation to determine whether the radiation emitted by the DUT complies with a threshold.

### EXAMPLE EMBODIMENTS

Example 1: An apparatus comprising (1) a chamber that includes a plurality of interior sides, (2) a plurality of antennas coupled to the plurality of interior sides, wherein the plurality of antennas are configured to receive radiation emitted by a device under test, and (3) a controller communicatively coupled to the plurality of antennas, wherein the controller is configured to obtain measurements of spurious emissions in the radiation.
Example 2: The apparatus of Example 1, wherein the plurality of interior sides comprise a ceiling and a plurality of interior walls, and the plurality of antennas comprise an antenna coupled to the ceiling and additional antennas coupled to the plurality of interior walls.
Example 3: The apparatus of either Example 1 or Example 2, wherein the plurality of interior walls comprises a first interior wall, a second interior wall, and a third interior wall, and the additional antennas comprise a first antenna secured to the first interior wall, a second antenna secured to the second interior wall, and a third antenna secured to the third interior wall.
Example 4: The apparatus of any of Examples 1-3, wherein the first antenna, the second antenna, and the third antenna are positioned substantially equidistant from the device under test.
Example 5: The apparatus of any of Examples 1-4, further comprising a switching device configured to selectively activate at least one of the plurality of antennas and selectively deactivate at least one other of the plurality of antennas.
Example 6: The apparatus of any of Examples 1-5, wherein the switching device is configured to enable the at least one of the plurality of antennas to take one or more of the measurements of spurious emissions.
Example 7: The apparatus of any of Examples 1-6, further comprising a movable platform configured to secure the device under test in place relative to the plurality of antennas.
Example 8: The apparatus of any of Examples 1-7, wherein the movable platform is further configured to rotate the device under test to enable the plurality of antennas to take the measurements of spurious emissions from different angles.
Example 9: The apparatus of any of Examples 1-8, wherein the plurality of antennas are configured to collectively take the measurements of spurious emissions across a range that includes at least 1 gigahertz and 21 gigahertz.
Example 10: The apparatus of any of Examples 1-9, further comprising a control interface secured to an external surface of the chamber, wherein the control interface is communicatively coupled to at least one of the plurality of antennas and/or the controller.
Example 11: The apparatus of any of Examples 1-10, further comprising radiation-absorbent material that covers a floor of the chamber.
Example 12: The apparatus of any of Examples 1-11, further comprising one or more beams composed of radiation-absorbent material coupled to the plurality of interior sides, wherein the plurality of antennas are secured to the one or more beams.
Example 13: The apparatus of any of Examples 1-12, further comprising a mobility feature configured to enable the chamber to move throughout a facility.
Example 14: The apparatus of any of Examples 1-13, wherein the chamber comprises a door and forms a full enclosure when the door is closed.
Example 15: The apparatus of any of Examples 1-14, wherein the controller is configured to determine whether the radiation emitted by the device under test complies with a threshold of spurious emissions.
Example 16: A system comprising (1) a device under test, (2) a chamber that includes a plurality of interior sides and houses the device under test, (3) a plurality of antennas coupled to the plurality of interior sides, wherein the plurality of antennas are configured to receive radiation emitted by the device under test, and (4) a controller communicatively coupled to the plurality of antennas, wherein the controller is configured to obtain measurements of spurious emissions in the radiation.
Example 17: The system of Example 16, wherein the plurality of interior sides comprise a ceiling and a plurality of interior walls, and the plurality of antennas comprise an antenna coupled to the ceiling and additional antennas coupled to the plurality of interior walls.
Example 18: The system of either of Example 16 or Example 17, wherein the plurality of interior walls comprises a first interior wall, a second interior wall, and a third interior wall, and the additional antennas comprise a first antenna secured to the first interior wall, a second antenna secured to the second interior wall, and a third antenna secured to the third interior wall.
Example 19: The system of any of Examples 16-18, wherein the first antenna, the second antenna, and the third antenna are positioned substantially equidistant from the device under test.
Example 20: A method comprising (1) positioning a device under test on a platform inside a chamber, (2) directing the device under test to emit radiation, (3) receiving the radiation via a plurality of antennas coupled to interior sides of the chamber, and (4) obtaining measurements of spurious emissions in the radiation via a controller to determine whether the radiation emitted by the device under test complies with a threshold.

The preceding description has been provided to enable others skilled in the art to best utilize various aspects of the exemplary embodiments disclosed herein. This exemplary description is not intended to be exhaustive or to be limited to any precise form disclosed. Many modifications and variations are possible without departing from the spirit and scope of the present disclosure. The embodiments disclosed herein should be considered in all respects illustrative and not restrictive. Reference may be made to any claims appended hereto and their equivalents in determining the scope of the present disclosure.

Unless otherwise noted, the terms “connected to” and “coupled to” (and their derivatives), as used in the specification and/or claims, are to be construed as permitting both direct and indirect (i.e., via other elements or components) connection. In addition, the terms “a” or “an,” as used in the specification and/or claims, are to be construed as meaning “at least one of.” Finally, for ease of use, the terms “including” and “having” (and their derivatives), as used in the specification and/or claims, are interchangeable with and have the same meaning as the word “comprising.”

What is claimed is:

1. An apparatus comprising:
a chamber that includes a plurality of interior sides;
a plurality of antennas coupled to the plurality of interior sides, wherein the plurality of antennas are configured to receive radiation emitted by a device under test; and
a controller communicatively coupled to the plurality of antennas, wherein the controller is configured to obtain measurements of spurious emissions in the radiation.

2. The apparatus of claim 1, wherein:
the plurality of interior sides comprise a ceiling and a plurality of interior walls; and
the plurality of antennas comprise:
an antenna coupled to the ceiling; and
additional antennas coupled to the plurality of interior walls.

3. The apparatus of claim 2, wherein:
the plurality of interior walls comprises a first interior wall, a second interior wall, and a third interior wall; and
the additional antennas comprise a first antenna secured to the first interior wall, a second antenna secured to the second interior wall, and a third antenna secured to the third interior wall.

4. The apparatus of claim 3, wherein the first antenna, the second antenna, and the third antenna are positioned substantially equidistant from the device under test.

5. The apparatus of claim 2, further comprising a switching device configured to:
selectively activate at least one of the plurality of antennas; and
selectively deactivate at least one other of the plurality of antennas.

6. The apparatus of claim 5, wherein the switching device is configured to enable the at least one of the plurality of antennas to take one or more of the measurements of the spurious emissions.

7. The apparatus of claim 1, further comprising a movable platform configured to secure the device under test in place relative to the plurality of antennas.

8. The apparatus of claim 7, wherein the movable platform is further configured to rotate the device under test to enable the plurality of antennas to take the measurements of the spurious emissions from different angles.

9. The apparatus of claim 1, wherein the plurality of antennas are configured to collectively take the measurements of the spurious emissions across a range that includes at least 1 gigahertz and 21 gigahertz.

10. The apparatus of claim 1, further comprising a control interface secured to an external surface of the chamber, wherein the control interface is communicatively coupled to at least one of:
the plurality of antennas; or
the controller.

11. The apparatus of claim 1, further comprising radiation-absorbent material that covers a floor of the chamber.

12. The apparatus of claim 1, further comprising one or more beams composed of radiation-absorbent material coupled to the plurality of interior sides, wherein the plurality of antennas are secured to the one or more beams.

13. The apparatus of claim 1, further comprising a mobility feature configured to enable the chamber to move throughout a facility.

14. The apparatus of claim 1, wherein the chamber comprises a door and forms a full enclosure when the door is closed.

15. The apparatus of claim 1, wherein the controller is configured to determine whether the radiation emitted by the device under test complies with a threshold of spurious emissions.

16. A system comprising:
a device under test;
a chamber that includes a plurality of interior sides and houses the device under test;
a plurality of antennas coupled to the plurality of interior sides, wherein the plurality of antennas are configured to receive radiation emitted by the device under test; and
a controller communicatively coupled to the plurality of antennas, wherein the controller is configured to obtain measurements of spurious emissions in the radiation.

17. The system of claim 16, wherein:
the plurality of interior sides comprise a ceiling and a plurality of interior walls; and
the plurality of antennas comprise:
an antenna coupled to the ceiling; and
additional antennas coupled to the plurality of interior walls.

18. The system of claim 17, wherein:
the plurality of interior walls comprises a first interior wall, a second interior wall, and a third interior wall; and
the additional antennas comprise a first antenna secured to the first interior wall, a second antenna secured to the second interior wall, and a third antenna secured to the third interior wall.

19. The system of claim 18, wherein the first antenna, the second antenna, and the third antenna are positioned substantially equidistant from the device under test.

20. A method comprising:
positioning a device under test on a platform inside a chamber;
directing the device under test to emit radiation;
receiving the radiation via a plurality of antennas coupled to interior sides of the chamber; and
obtaining measurements of spurious emissions in the radiation via a controller to determine whether the radiation emitted by the device under test complies with a threshold.
